(19) United States
(12) Patent Application Publication
(10) Pub. No.: US 2009/0188702 A1
(43) Pub. Date: Jul. 30, 2009

(54) FLEXIBLE PRINTED WIRING BOARD AND ELECTRONIC APPARATUS

(75) Inventors: Kiyomi Muro, Tokyo (JP); Akihiko Happoya, Tokyo (JP); Yasuki Torigoshi, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/334,413

(22) Filed: Dec. 12, 2008

(30) Foreign Application Priority Data
Jan. 25, 2008 (JP) 2008-015116

(51) Int. Cl. H05K 1/00

(52) U.S. Cl. 174/254

(57) ABSTRACT

An embodiment of a flexible printed wiring board includes: a base layer comprising one surface and the other surface, the one surface being exposed; a signal layer formed on the other surface of the base layer; a cover layer stacked on the base layer to cover the signal layer; and a ground layer coated on the cover layer to cover the signal layer, the ground layer comprising a conductive paste in which metal powder and metal nanoparticles are mixed.

### CROSS-REFERENCE TO RELATED APPLICATIONS

This application is based upon and claims the benefit of priority from Japanese Patent Application No. 2008-015116, filed Jan. 25, 2008, the entire contents of which are incorporated herein by reference.

### BACKGROUND

1. Field

The present invention relates to a flexible printed wiring board which is preferably used in a circuit handling a high-frequency band signal of the differential transmission system.

2. Description of Related Art

A flexible printed wiring board is often used in an information processing apparatus, due to its flexibility that enables it to be mounted in a case in a bent state, and its high degree of freedom in wiring. In accordance with increases of the processing speed and circuit density in an information processing apparatus, a flexible printed wiring board mounted in a case of such an apparatus has been requiring a technique to form, by using print wiring, a transmission line for transmitting a high-frequency band signal in consideration of a transmission loss. This is based on an outlook of transition from the microwave (UHF) band to the centimeter wave (SHF) band, or from the centimeter wave band to the millimeter wave (EHF) band.

When the signal transmission speed is not so high, a transmission line of the single-end type is frequently used. When a signal of several hundred MHz or higher is to be transmitted, a transmission line of the signal transmission form in which a voltage reduction of the signal and the differential transmission system are combined with each other is often used. In the differential transmission system, one signal is transformed to two signals of positive and negative phases, and the signals are transmitted through two parallel transmission lines, respectively. The system has characteristics of signal transmission at a low voltage and high noise resistance.

As a transmission line forming technique of this kind, conventionally, a flexible wiring board of the double-layered copper foil structure (double-sided FPC) has been proposed in which a first device handling differential signals is disposed in one end side, a second device handling the differential signals is disposed in the other end side, and the two devices are connected to each other by a differential signal line pair having a constant impedance (see JP-A-2005-260066).

In the above-described double-sided FPC, the first layer is configured as a signal layer, the second layer is configured as a ground layer, and differential transmission lines are disposed in the signal layer, whereby a differential signal circuit of a low transmission loss can be formed. However, the double-sided FPC has a structure in which conductive layers made of a copper foil are formed on the both faces of an insulative board, and hence is inferior in flexibility to a flexible board of the single-layered copper foil structure (single-sided FPC). Therefore, there is a limitation in the use of the double-sided FPC in a movable portion, since the durability might become low.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a side section view showing the configuration of main portions of a flexible printed wiring board of an embodiment of the invention;

FIG. 2 is a plan view showing the configuration of the flexible printed wiring board of the embodiment;

FIG. 3 is a plan view showing the configuration of main portions of the flexible printed wiring board of the embodiment;

FIGS. 4A and 4B are views showing a model of a conductive path of a conductive paste forming a ground layer of the flexible printed wiring board of the embodiment;

FIG. 5 is a view showing transmission loss characteristics of the flexible printed wiring board of the embodiment; and

FIG. 6 is a side section view showing the configuration of an electronic apparatus in which the flexible printed wiring board of the embodiment is mounted.

### DETAILED DESCRIPTION

Various embodiments according to the invention will be described hereinafter with reference to the accompanying drawings. In general, according to one embodiment of the invention, a flexible printed wiring board includes: a base layer comprising one surface and the other surface, the one surface being exposed; a signal layer formed on the other surface of the base layer; a cover layer stacked on the base layer to cover the signal layer; and a ground layer coated on the cover layer to cover the signal layer, the ground layer comprising a conductive paste in which metal powder and metal nanoparticles are mixed.

Hereinafter, an embodiment of the invention will be described with reference to the drawings.

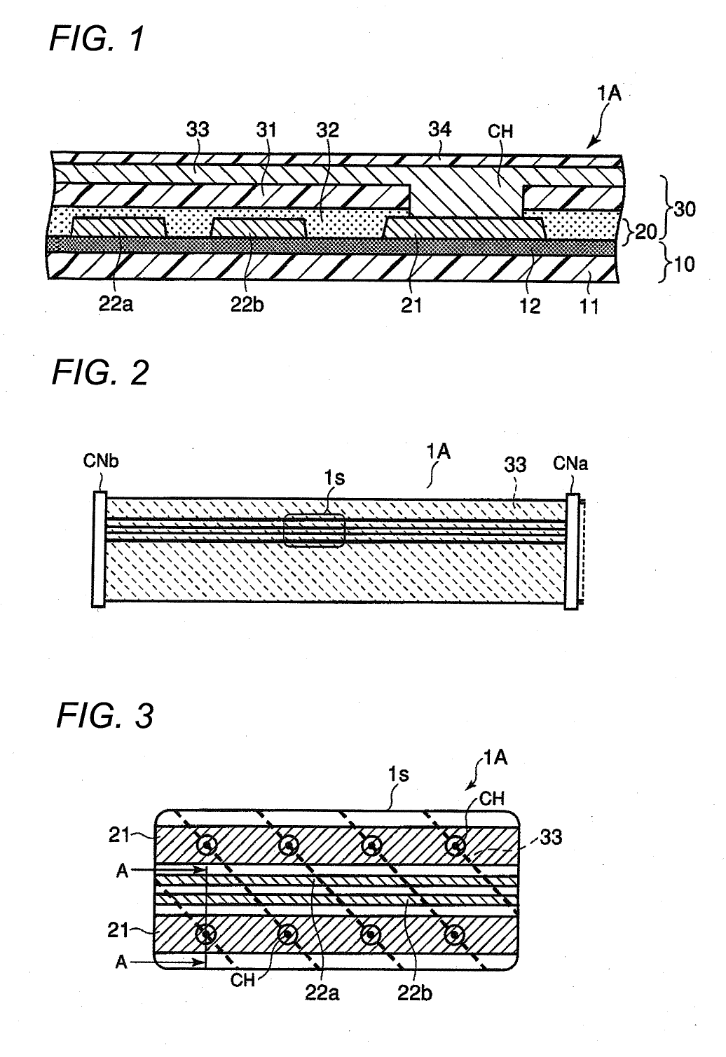

FIG. 1 shows a sectional structure of a flexible printed wiring board of an embodiment of the invention. FIG. 2 shows a planar structure of the whole flexible printed wiring board. FIG. 3 shows a planar structure in which a part of FIG. 2 is enlargedly shown. FIG. 1 shows the section structure taken along the line I-I in FIG. 3, and FIG. 3 enlargedly shows a portion 1s shown in FIG. 2.

As shown in FIG. 1, the flexible printed wiring board 1A of the embodiment of the invention has: a base layer 10 in which one surface is exposed; a signal layer 20 which is formed on the other surface of the base layer 10; a cover layer 30 which covers the signal layer 20, and which is stacked on the base layer 10; and a ground layer 33 which covers the cover layer to cover the signal layer 20, and which is formed by a conductive paste in which metal powder and metal nanoparticles are mixed.

The base layer 10 is configured by a base polyimide 11 and a base layer adhesive 12. The surface of the base layer adhesive 12 functions as a pattern forming face for the signal layer 20, and a wiring layer configured by a copper pattern is formed.

In the signal layer 20, the base layer adhesive 12 of the base layer 10 is used as an insulative substrate, and signal lines 22a, 22b which are paired on the substrate, and ground lines 21 which extend in parallel to the signal lines 22a, 22b are formed on the substrate. The signal lines 22a, 22b are configured by two wiring patterns (copper pattern) which are parallel to each other on the face of the base layer 10 (on the face of the adhesive 12), and function as signal transmission lines of the differential transmission system (differential signal transmission lines). As shown in FIG. 3, the ground lines 21 extend along the signal lines 22a, 22b, and are disposed on the both sides of the signal lines 22a, 22b via a predetermined gap, respectively.

The cover layer 30 is configured by a cover layer polyimide 31 and a cover layer adhesive 32. The cover 30 is covered by the ground layer 33, and the ground layer 33 is covered by a protective layer (overcoat) 34.

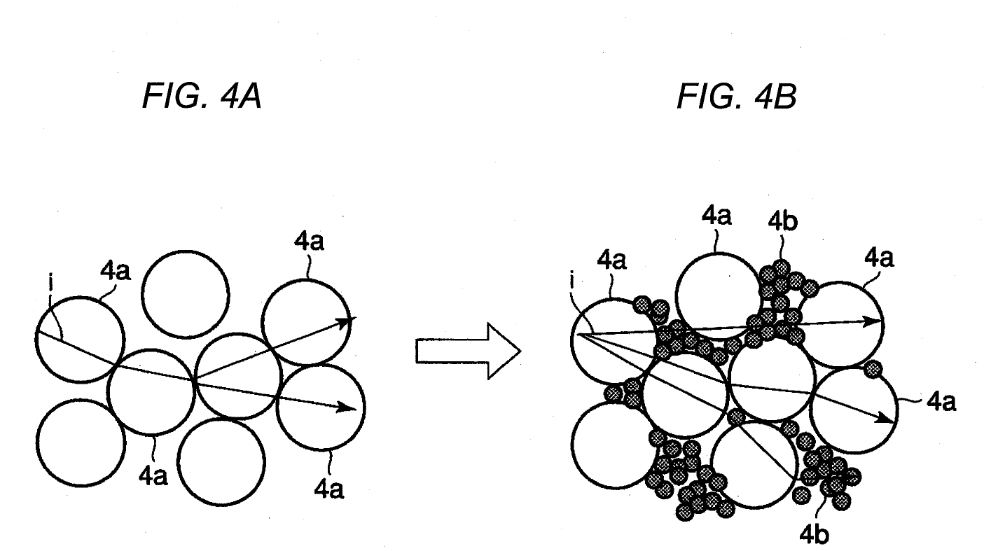

The ground layer 33 is configured by a hybrid paste (silver hybrid paste) in which silver powder and silver nanoparticles are mixed, and which has a volume resistivity (specific resistance) of 30 μΩ·cm or less. A silver paste which is usually used has a volume resistivity of about 45 μΩ·cm. The structural difference between the silver hybrid paste and a silver paste will be described later with reference to FIGS. 4A and 4B.

The ground lines 21 which are disposed in the signal layer 20 extend along the wiring (laying) direction of the signal lines 22a, 22b which form the differential transmission lines, and are conductively joined to the ground layer 33 at predetermined intervals. In the embodiment, as shown in FIG. 3, conductive joining openings (CH) through which the copper pattern of the ground lines 21 is exposed are disposed at the predetermined intervals in area portions of the cover layer 30 situated on the ground lines 21, the hybrid paste is applied through the openings (CH), and the hybrid paste fills the openings (CH) as shown in FIG. 1, whereby the ground lines 21 are conductively joined to the ground layer 33 in a spot-like manner. The conductive joining between the ground lines 21 and the ground layer 33 allows the ground lines 21 to be held in a low-resistance (low-impedance) and equipotential state with respect to the extension direction. The hybrid paste which constitutes the ground layer 33 is covered by the overcoat member, and the protective film (cover layer 30) in which the surface is flat is formed on the ground layer 33 as shown in FIG. 1.

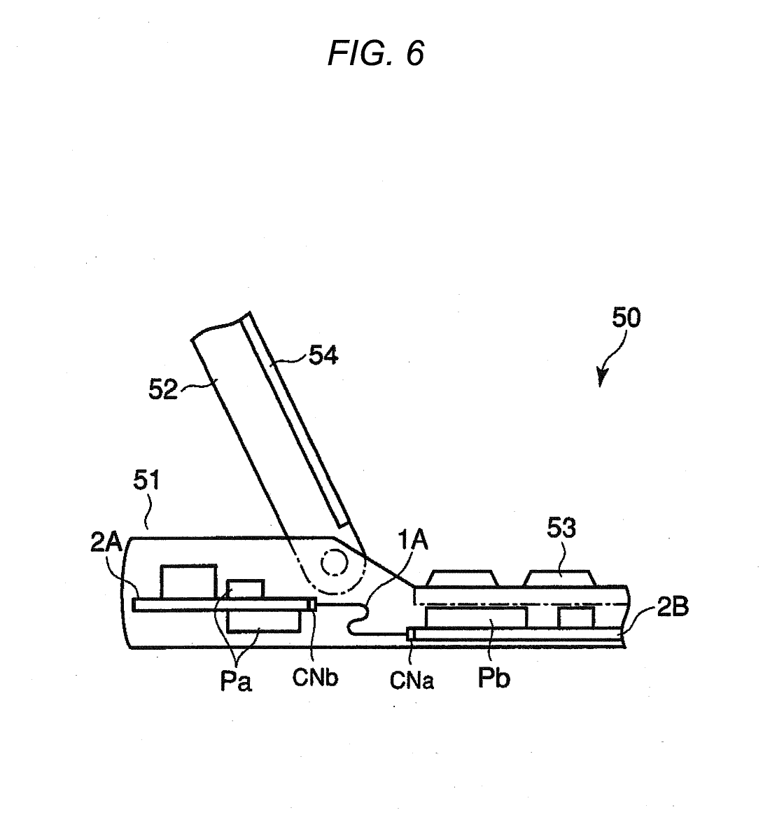

The ground lines 21 which are formed in the signal layer 20, and the signal lines 22a, 22b which form the differential transmission lines are connected to a signal transmission circuit which handles differential signals (not shown), in an impedance matching state via connectors CNa, CNb shown in FIG. 2 (see FIG. 6).

The thus configured flexible printed wiring board 1A is a single-sided FPC which has the ground layer 33 made of the hybrid paste having a volume resistivity (specific resistance) of 30 μΩ·cm or less, and which is configured by the single layer copper foil. Therefore, the wiring board can solve the above-discussed problem of a double-sided FPC (the flexibility is inferior to a single-sided FPC, and therefore the durability is low in the use in a movable portion), and improve the degradation of a transmission loss in the high-frequency band. For example, it is possible to realize a transmission line which can be sufficiently applicable to signal transmission of a transmission speed of 3 Gbps according to the SATA2 (Serial ATA2) specification, and in which the transmission loss in the high-frequency band is low.

A conductive path of the silver hybrid paste for forming the ground layer 33 is modeled in FIGS. 4A and 4B, while comparing with that of a silver paste which is usually used. FIG. 4A shows a conductive path of a silver paste which is usually used. FIG. 4B shows that of the silver hybrid paste for forming the ground layer 33. In FIGS. 4A and 4B, i denotes a conductive path, 4a denotes silver powder, and 4b denotes silver nanoparticles of about several nanometers. The silver paste shown in FIG. 4A is configured by mixing the silver powder 4a with a binder resin (not shown) to be formed into a paste. The silver hybrid paste shown in FIG. 4B is configured by mixing the silver powder 4a, the silver nanoparticles 4b, and a binder resin (not shown) with one another to be formed into a paste. In FIG. 4B, the silver nanoparticles 4b enhance the electrical contacts between particles of the silver powder 4a.

The conductive path (i) is formed by physical contacts of metal particles in the paste. In the silver hybrid paste shown in FIG. 4B, therefore, the silver nanoparticles 4b are interposed between particles of the silver powder 4a to form the dense conductive path (i), so that the conductivity is remarkably improved, and the volume resistivity can be set to be 30 μΩ·cm or less by adjusting the mixture ratio of the silver powder 4a and the silver nanoparticles 4b.

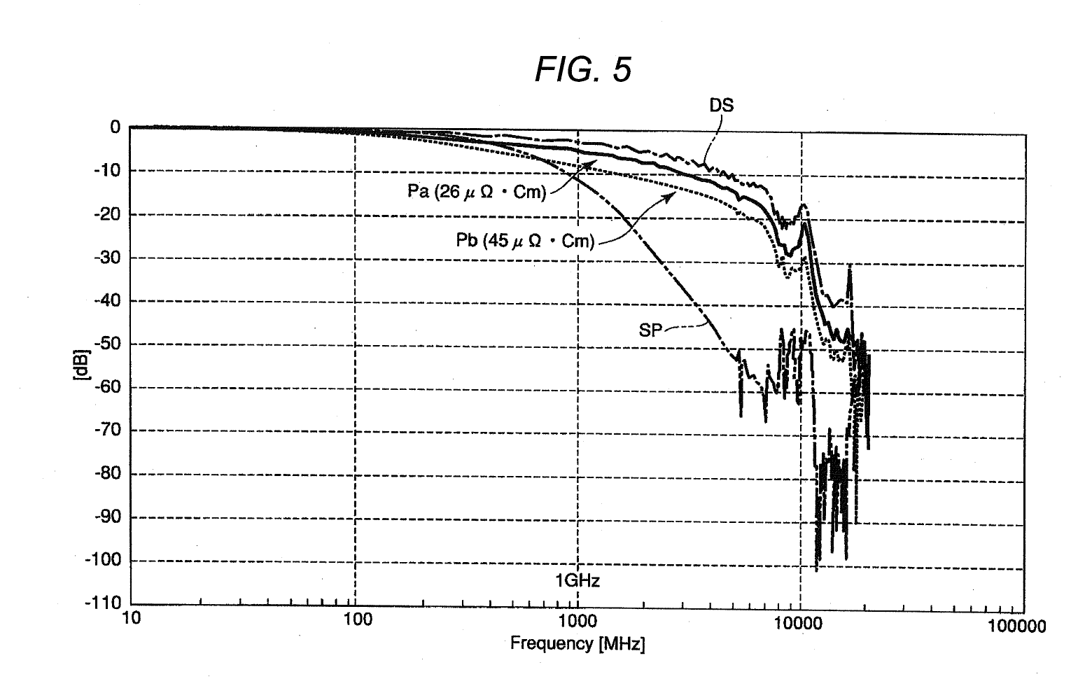

FIG. 5 shows a comparison of transmission loss characteristics between differential transmission lines in which the silver hybrid paste (volume resistivity: 26 μΩ·cm) shown in FIG. 4B is used in the ground layer, and those in which the silver paste (volume resistivity: 45 μΩ·cm) shown in FIG. 4A is used in the ground layer. In FIG. 5, Pa indicated by the solid line shows the transmission loss characteristics of the differential transmission lines in which the silver hybrid paste shown in FIG. 4B is used in the ground layer, and Pb indicated by the broken line shows those in the differential transmission lines in which the silver paste shown in FIG. 4A is used in the ground layer. DS indicated by the dash-dot line shows the transmission loss characteristics of differential transmission lines in which a copper foil of one layer of a double-sided FPC is used as a ground layer, and SP shows those of differential transmission lines in which a ground layer is formed by a metal sputter film. From the transmission loss characteristics shown in FIG. 5, it is seen that the transmission loss of the differential transmission lines in which the silver hybrid paste is used in the ground layer is lower than that of the differential transmission lines in which the silver paste is used in the ground layer, similar to that of the differential transmission lines in which a ground layer is formed by a copper foil, and can be sufficiently applicable to transmission of a high-frequency signal at a transmission speed of about 3 Gbps.

Since the flexible printed wiring board 1A of the above-described embodiment of the invention has the single-sided FPC structure, the flexibility is superior as compared to a double-sided FPC, and, even when the wiring board is used in a movable portion, the durability is excellent. Moreover, the transmission lines are formed by using the silver hybrid paste in the ground layer 33, whereby the transmission loss in the high-frequency band is improved, so that signal transmission of a transmission speed of 3 Gbps according to the Serial ATA2 (SATA2) specification is enabled.

FIG. 6 shows a configuration example in which the flexible printed wiring board 1A of the above-described embodiment is applied to a small electronic apparatus such as a handy portable computer.

Referring to FIG. 6, a display unit case 52 is rotatably disposed on a main unit 51 of a portable computer 50 through a hinge mechanism. A keyboard 53 which functions as an operation input unit is disposed on the main unit 51. A display device 54 using a liquid crystal panel or the like is disposed in the display unit case 52.

The above-described flexible printed wiring board 1A, and circuit boards 2A, 2B each of which is configured by a rigid board are disposed in the main unit 51. The circuit boards are connector-connected to the flexible printed wiring board 1A, and mutually perform signal transmission by the differential transmission system via the flexible printed wiring board 1A. Transmitting/receiving circuit elements PA, PB which constitute signal input/output ports in the differential transmission system are disposed in the circuit boards 2A, 2B. The transmitting/receiving circuit elements PA, PB transmit and receive signals (differential transmission signals) through the signal lines (differential transmission lines) 22a, 22b disposed on the flexible printed wiring board 1A.

As shown in FIGS. 1 to 3, the flexible printed wiring board 1A through which the circuit boards 2A, 2B are circuit connected to each other has: the base layer 10 in which one surface is exposed; the signal layer 20 which is formed on the other surface of the base layer 10; the cover layer 30 which covers the signal layer 20, and which is stacked on the base layer 10; and the ground layer 33 which covers the cover layer to cover the signal layer 20. The ground layer 33 is configured by the silver hybrid paste in which silver powder and silver nanoparticles are mixed, and which has a volume resistivity (specific resistance) of 30 μΩ·cm or less. Since the flexible printed wiring board 1A has the single-sided FPC structure, the flexibility is superior as compared to a double-sided FPC, and, even when the wiring board is used in a movable portion, the durability is excellent. Moreover, the transmission lines are formed by using the silver hybrid paste in the ground layer 33, whereby the transmission loss in the high-frequency band is improved, so that signal transmission of a transmission speed of 3 Gbps according to the SATA2 (Serial ATA2) specification is enabled.

In the embodiment, the ground layer 33 is formed by a silver hybrid paste. Alternatively, a hybrid paste in which nanoparticles of a metal other than silver are mixed, such as that in which gold powder and gold nanoparticles are mixed, or that in which silver powder and gold nanoparticles are mixed may be used. In the embodiment, with exemplifying the strip-like flexible printed wiring board, the signal layer comprising: the two signal line (differential transmission lines); and the two ground lines which extend in parallel to the differential transmission lines so as to sandwich the two signal line has been described. However, the invention is not restricted to this. In an execution phase, modifications or changes can be made without departing from the spirit of the invention.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A flexible printed wiring board comprising:
a base layer comprising a first surface and a second surface, the first surface being exposed;
a signal layer formed on the second surface of the base layer;
a cover layer stacked on the base layer to cover the signal layer; and
a ground layer coated on the cover layer to cover the signal layer, the ground layer comprising a conductive paste comprised of metal powder and metal nanoparticles.

2. The flexible printed wiring board of claim 1,
wherein the signal layer comprises differential transmission lines.

3. The flexible printed wiring board of claim 2,
wherein the signal layer comprises a ground line extending in parallel to the differential transmission lines.

4. The flexible printed wiring board of claim 3,
wherein the ground line is conductively joined to the ground layer at given intervals along a wiring direction of the differential transmission lines.

5. The flexible printed wiring board of claim 4,
wherein the cover layer comprises openings; and
the ground line is conductively joined portions of the ground layer in a spotted manner through the openings.

6. The flexible printed wiring board of claim 5, further comprising: a protective layer;
wherein the ground layer comprising the conductively joined portions is covered by the protective layer.

7. The flexible printed wiring board of claim 1,
wherein the conductive paste comprises a hybrid paste comprised of silver powder and silver nanoparticles.

8. The flexible printed wiring board of claim 7,
wherein the hybrid paste has a volume resistivity of 30 μΩ·cm or less.

9. The flexible printed wiring board of claim 1,
wherein the flexible printed wiring board comprises a circuit component that is configured to transmit a high-frequency signal having a transmission speed according to the Serial ATA2 specification.

10. An electronic apparatus comprising:
an electronic apparatus body;
a high-frequency circuit disposed in the electronic apparatus body and configured to process a differential signals, the high-frequency circuit comprising signal transmission lines; and
a flexible printed wiring board connected to the signal transmission lines of the high-frequency circuit;
wherein the flexible printed wiring board comprises:
a base layer comprising a first surface and a second surface, the first surface being exposed;
a signal layer formed on the other surface of the base layer;
a cover layer stacked on the base layer to cover the signal layer; and
a ground layer coated on the cover layer to cover the signal layer, the ground layer comprising a conductive paste comprised of metal powder and metal nanoparticles.

11. The electronic apparatus of claim 10,
wherein the conductive paste comprises a hybrid paste comprised of silver powder and silver nanoparticles, the hybrid paste having a volume resistivity of 30 μΩ·cm or less.
